(19) United States
(12) Patent Application Publication
(10) Pub. No.: US 2023/0279266 A1
(43) Pub. Date: Sep. 7, 2023

(54) POLISHING LIQUID COMPOSITION FOR SILICON OXIDE FILMS

(71) Applicant: Kao Corporation, Tokyo (JP)

(72) Inventors: Masaki INOUE, Wakayama (JP); Norihito YAMAGUCHI, Wakayama (JP)

(73) Assignee: Kao Corporation, Tokyo (JP)

(21) Appl. No.: 18/030,378

(22) PCT Filed: Sep. 30, 2021
(86) PCT No.: PCT/JP2021/036148

§ 371 Date: Apr. 5, 2023

(30) Foreign Application Priority Data
Oct. 5, 2020 (JP) 2020-168625
Sep. 28, 2021 (JP) 2021-157683

(51) Int. Cl. C09G 1/02; H01L 21/3105

(52) U.S. Cl. CPC C09G 1/02; H01L 21/31053

(57) ABSTRACT

In one aspect, the present disclosure provides a polishing liquid composition for a silicon oxide film that can achieve both of an improved polishing rate for a silicon oxide film and a reduced line width dependence of the polishing rate at raised areas in a pattern layer of raised and trench areas.

One aspect of the present disclosure is directed to a polishing liquid composition for a silicon oxide film that contains: cerium oxide particles (component A); a compound represented by Formula (I) or Formula (II) below (component B); a nitrogen-containing heteroaromatic compound in which at least one hydrogen atom is substituted with a hydroxyl group (component C); and an aqueous medium.

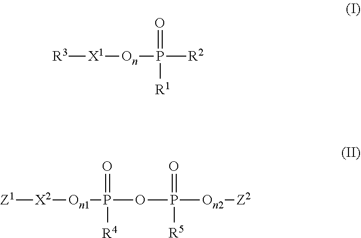

### TECHNICAL FIELD

The present disclosure relates to a polishing liquid composition for a silicon oxide film, a method for producing a semiconductor substrate using the same, and a polishing method using the same.

### BACKGROUND ART

The recent rapid progress in multilayer semiconductor devices with high definition has promoted the use of more sophisticated patterning technologies, and this complicates the surface structure of semiconductor devices and increases a step height on the surface. In the production of the semiconductor devices, chemical mechanical polishing (CMP) technique is used for planarizing such a step height (raised and trench areas) formed on the substrate. As the definition becomes higher, the polishing liquid composition used therefor is required to provide a high level of planarity while providing high-speed polishing.

For example, JP 2020-080399A (Patent Document 1) proposes a polishing liquid composition for a silicon oxide film that contains cerium oxide particles, a nitrogen-containing heteroaromatic ring compound such as 2-hydroxypyridine N-oxide, and an aqueous medium.

JP 2015-534725 A (Patent Document 2) proposes a polishing composition that contains a pyrrolidone polymer (e.g., polyvinylpyrrolidone), an amino phosphonic acid, a tetraalkylammonium salt, and water.

### SUMMARY OF INVENTION

One aspect of the present disclosure is directed to a polishing liquid composition for a silicon oxide film that contains: cerium oxide particles (component A); a compound represented by Formula (I) or Formula (II) below (component B); a nitrogen-containing heteroaromatic compound in which at least one hydrogen atom is substituted with a hydroxyl group (component C); and an aqueous medium.

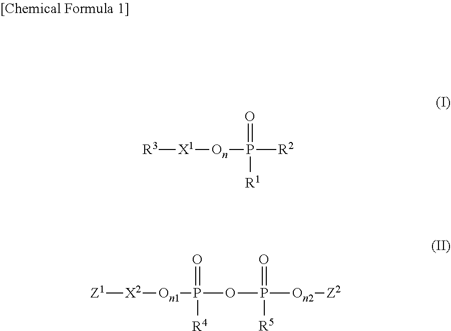

In Formula (I), R¹ and R² are the same or different and represent a hydroxyl group or a salt thereof, R³ represents H, —NH₂, —NHCH₃, —N(CH₃)₂, —N⁺(CH₃)₃, an alkyl group, a phenyl group, a cytidine group, a guanidino group, or an alkylguanidino group, X¹ represents a bond or an alkylene group having 1 to 12 carbon atoms, and n represents 0 or 1.

In Formula (II), R⁴ and R⁵ are the same or different and represent a hydroxyl group or a salt thereof, Z¹ represents H or —N⁺(CH₃)₃, Z² represents a cytidine group, X² represents a bond or an alkylene group having 1 to 12 carbon atoms, and n1 and n2 are the same or different and represent 0 or 1.

One aspect of the present disclosure is directed to a method for producing a semiconductor substrate, including a process of polishing a film to be polished with use of the polishing liquid composition for a silicon oxide film of the present disclosure.

One aspect of the present disclosure is directed to a polishing method, including a process of polishing a film to be polished with use of the polishing liquid composition of the present disclosure, wherein the film to be polished is a silicon oxide film that is formed in a production process of a semiconductor substrate.

### DESCRIPTION OF EMBODIMENTS

The progress in the multilayering technique and in the definition of the semiconductor devices requires the CMP polishing to further improve the polishing rate with respect to a silicon oxide film (film to be polished) to eliminate the step height due to multilayering.

Further, in the case of polishing a pattern layer of raised and trench areas formed on the substrate, the polishing rate varies depending on the size (line width) of raised areas, i.e., the polishing rate is largely dependent upon the line width of the raised areas (line width dependence). Therefore, there has been a demand for a polishing liquid composition that can reduce the line width dependence of the polishing rate at raised areas while capable of planarizing every kind of pattern.

The polishing liquid composition disclosed in Patent Document 1 contains a nitrogen-containing heteroaromatic ring compound (e.g., 2-hydroxypyridine N-oxide) that is highly effective in improving the polishing rate with respect to wiring having a narrow line width. However, as the addition amount of the compound is increased to improve the polishing rate, the polishing rate with respect to wiring having a wide line width tends to decrease. Lowering of the line width dependence is desired.

The polish composition disclosed in Patent Documents 2 contains a pyrrolidone polymer. The polish composition has favorable slurry stability, but the effect of improving the polishing rate is not satisfactory.

In view of the above, the present disclosure provides a polishing liquid composition for a silicon oxide film that can achieve both of an improved polishing rate for a silicon oxide film and a reduced line width dependence of the polishing rate at raised areas in a pattern layer of raised and trench areas, a method for producing a semiconductor substrate using the same, and a polishing method using the same.

The present inventors conducted intensive studies and made the findings that a combination of a specific compound and a specific nitrogen-containing heteroaromatic compound can improve the polishing rate for a silicon oxide film while reducing the line width dependence of the polishing rate at raised areas in a pattern layer of raised and trench areas and improving planarity.

In one aspect, the present disclosure provides a polishing liquid composition for a silicon oxide film that can achieve both of an improved polishing rate for a silicon oxide film and a reduced line width dependence of the polishing rate at raised areas in a pattern layer of raised and trench areas.

Specifically, one aspect of the present disclosure is directed to a polishing liquid composition for a silicon oxide film (hereinafter, also referred to as a “polishing liquid composition of the present disclosure”) that includes: cerium oxide particles (component A); a compound represented by Formula (I) or Formula (II) indicated above (component B); a nitrogen-containing heteroaromatic compound in which at least one hydrogen atom is substituted with a hydroxyl group (component C); and an aqueous medium.

In one or more embodiments, the polishing liquid composition of the present disclosure can achieve both of an improved polishing rate for a silicon oxide film and a reduced line width dependence of the polishing rate at raised areas in a pattern layer of raised and trench areas (improvement of planarity).

The details of the mechanism of the effects of the present disclosure are not fully clear, but the following are considered.

A certain type of nitrogen-containing heteroaromatic compound (component C) is known to promote electron transfer of a silicon oxide film (object to be polished) through reduction of cerium oxide particles, increasing a chemical polishing power. Thus, the component C can increase the polishing rate, but as another function, it adsorbs on the silicon oxide film and exhibits polishing inhibition ability. If the addition amount of the component C is largely increased to improve the polishing rate, the polishing rate especially at raised areas having a wide line width decreases markedly. Therefore, to further improve the polishing rate, an agent other than the component C is desired that can exhibit an effect of improving the polishing rate at raised areas having a wide line width.

In the present disclosure, it has been found that a strong interaction of the component B with the cerium oxide contributes to the improvement in the polishing rate at raised areas having a wide line width and lowers the line width dependence due to the component C. The details are unclear, but the component B increases the frequency with which the (100) plane of the cerium oxide particles comes into contact with the silicon oxide film, whereas the component C particularly promotes the electron transfer of the (100) plane of the cerium oxide particles to the silicon oxide film and the progress of polishing, and thus improving the polishing rate and planarity.

The present disclosure, however, is not limited to these mechanisms.

[Cerium Oxide Particles (Component A)]

The polishing liquid composition of the present disclosure contains cerium oxide (hereinafter, also referred to as “ceria”) particles (hereinafter, also referred to as a “component A” simply) as polishing abrasive grains. The component A may be either positively charged ceria or negatively charged ceria. The chargeability of the component A can be confirmed by measuring a potential (surface potential) on the surface of the abrasive grains with, e.g., an electroacoustic method, or an electrokinetic sonic amplitude (ESA) method. The surface potential can be measured with, e.g., “ZetaProbe” (manufactured by Kyowa Interface Science Co., Ltd.) and specifically by a method as described in Examples. The component A may be one kind or a combination of two or more kinds. The component A may be one kind or a combination of two or more kinds. The chargeability of the abrasive grains is not particularly limited, and positively charged ceria is preferably used from the viewpoint of improving the polishing rate.

The production method, shape, and surface state of the component Aare not limited. Examples of the component A include colloidal ceria, irregularly-shaped ceria, and ceria-coated silica. The colloidal ceria can be obtained by a build-up process, e.g., in the method described in Examples 1 to 4 of JP 2010-505735 A. The irregularly-shaped ceria may be, e.g., crushed ceria. An embodiment of the crushed ceria may be, e.g., calcined crushed ceria obtained by calcining and crushing a cerium compound such as cerium carbonate or cerium nitrate. Another embodiment of the crushed ceria may be, e.g., single crystal crushed ceria obtained by wet-crushing ceria particles in the presence of an inorganic acid or organic acid. The inorganic acid used in the wet-crushing process may be, e.g., a nitric acid. The organic acid used in the wet-crushing process may be, e.g., an organic acid having a carboxyl group. Specifically, the organic acid may be at least one selected from polycarboxylate such as ammonium polyacrylate, picolinic acid, glutamic acid, aspartic acid, aminobenzoic acid, and p-hydroxybenzoic acid. For example, positively charged ceria is obtained by use of at least one selected from picolinic acid, glutamic acid, aspartic acid, aminobenzoic acid, and p-hydroxybenzoic acid in the wet-crushing process, whereas negatively charged ceria is obtained by use of polycarboxylate such as ammonium polyacrylate in the wet-crushing process. The wet-crushing process may be, e.g., wet-crushing with a planetary bead mill or the like. The ceria-coated silica may be, e.g., composite particles obtained by covering at least a part of the surface of individual silica particles with granular ceria, e.g., with the method described in Examples 1 to 14 of JP 2015-63451 A or Examples 1 to 4 of JP 2013-119131 A. The composite particles can be obtained by, e.g., deposition of ceria on the silica particles.

The component A may have, e.g., a substantially spherical shape, a polyhedral shape, or a raspberry-like shape.

The average primary particle diameter of the component A is preferably 5 nm or more, more preferably 10 nm or more, and further preferably 20 nm or more from the viewpoint of improving the polishing rate and planarity. Moreover, the average primary particle diameter of the component A is preferably 300 nm or less, more preferably 200 nm or less, further preferably 150 nm or less, still further preferably 100 nm or less, and even further preferably 50 nm or less from the viewpoint of reducing the occurrence of polishing scratches. In the present disclosure, the average primary particle diameter of the component A is calculated using a BET specific surface area S (m²/g) that is determined by a BET (nitrogen adsorption) method. The BET specific surface area can be measured by a method described in Examples.

The content of the component Ain the polishing liquid composition of the present disclosure is preferably 0.001% by mass or more, more preferably 0.01% by mass or more, further preferably 0.05% by mass or more, still further preferably 0.1% by mass or more, yet further preferably 0.125% by mass or more, and even further preferably 0.15% by mass or more from the viewpoint of improving the polishing rate and planarity. Moreover, the content of the component A is preferably 6% by mass or less, more preferably 3% by mass or less, further preferably 1% by mass or less, still further preferably 0.5% by mass or less, and even further preferably 0.3% by mass or less from the viewpoint of reducing the occurrence of polishing scratches. More specifically, the content of the component A in the polishing liquid composition of the present disclosure is preferably 0.001% by mass or more and 6% by mass or less, more preferably 0.01% by mass or more and 6% by mass or less, further preferably 0.05% by mass or more and 3% by mass or less, still further preferably 0.1% by mass or more and 1% by mass or less, yet further preferably 0.125% by mass or more and 0.5% by mass or less, and even further preferably 0.15% by mass or more and 0.3% by mass or less. When the component A is a combination of two or more kinds, the content of the component A refers to the total content of the two or more kinds.

[Compound Represented by Formula (I) or Formula (II) (Component B)]

The polishing liquid composition of the present disclosure contains a compound represented by Formula (I) or Formula (II) below (hereinafter, also referred to as a “component B” simply). The component B may be one kind or a combination of two or more kinds.

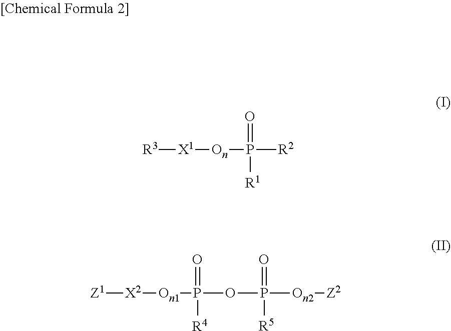

In Formula (I), R¹ and R² are the same or different and represent a hydroxyl group or a salt thereof, R³ represents H, —NH₂, —NHCH₃, —N(CH₃)₂, —N⁺(CH₃)₃, an alkyl group, a phenyl group, a cytidine group, a guanidino group, or an alkylguanidino group, X¹ represents a bond or an alkylene group having 1 to 12 carbon atoms, and n represents 0 or 1.

In Formula (II), R⁴ and R⁵ are the same or different and represent a hydroxyl group or a salt thereof, Z¹ represents H or —N⁺(CH₃)₃, Z² represents a cytidine group, X² represents a bond or an alkylene group having 1 to 12 carbon atoms, and n1 and n2 are the same or different and represent 0 or 1.

In Formula (I), both of R¹ and R² are preferably a hydroxyl group from the viewpoint of reducing the salt concentration and improving the stability.

R³ is preferably H, —NH₂, —N⁺(CH₃)₃, an alkyl group, a phenyl group, a cytidine group, or an alkylguanidino group from the viewpoint of improving the polishing rate and planarity. R³ is preferably a phenyl group, a cytidine group, or a guanidino group, and more preferably a phenyl group from the viewpoint of reducing the line width dependence. As the alkyl group, an alkyl group having 1 to 12 carbon atoms is preferable, an alkyl group having 2 to 6 carbon atoms is more preferable, and an alkyl group having 4 carbon atoms (butyl group) is further preferable, from the viewpoint of improving the polishing rate and planarity. As the alkylguanidino group, an alkylguanidino group having 2 to 12 carbon atoms is more preferable, an alkylguanidino group having 2 to 4 carbon atoms is further preferable, a methylguanidino group is still further preferable, and 1-methylguanidino group is even further preferable, from the viewpoint of improving the polishing rate and planarity.

X¹ is preferably a bond or an alkylene group having 12 or less carbon atoms, more preferably a bond or an alkylene group having 10 or less carbon atoms, further preferably a bond or an alkylene group having 8 or less carbon atoms, still further preferably a bond or an alkylene group having 6 or less carbon atoms, still further preferably a bond or an alkylene group having 4 or less carbon atoms, yet further preferably a bond or an alkylene group having 2 carbon atoms (ethylene group), and even further preferably a bond, from the viewpoint of improving the solubility.

In one or more embodiments, in Formula (I), R¹ and R² are the same or different and represent a hydroxyl group or a salt thereof, R³ represents a phenyl group, a cytidine group, a guanidino group, or an alkylguanidino group, X¹ represents a bond or an alkylene group having 1 to 4 carbon atoms, and n represents 0 or 1, from the viewpoint of improving the polishing rate and planarity.

In one or more embodiments, in Formula (I), R¹ and R² are the same or different and represent a hydroxyl group or a salt thereof, R³ represents a phenyl group, X¹ represents a bond, and n represents 0 or 1, from the viewpoint of improving the polishing rate and planarity.

In Formula (II), R⁴ and R⁵ are preferably a salt of a hydroxyl group from the viewpoint of availability.

X² is preferably an alkylene group having 1 to 12 carbon atoms, more preferably an alkylene group having 1 to 10 carbon atoms, further preferably an alkylene group having 1 to 8 carbon atoms, still further preferably an alkylene group having 1 to 6 carbon atoms, still further preferably an alkylene group having 1 to 4 carbon atoms, yet further preferably an alkylene group having 2 or 3 carbon atoms, and even further preferably an alkylene group having 2 carbon atoms (ethylene group), from the viewpoint of improving the polishing rate and planarity.

Further, n1 and n2 are preferably 1 from the viewpoint of improving the polishing rate and planarity.

Examples of the component B include creatinol phosphate or a salt thereof, O-phosphorylethanolamine or a salt thereof, phosphocholine chloride sodium salt hydrate or a salt thereof, alkylphosphonic acid such as butylphosphonic acid or a salt thereof, phenylphosphonic acid or a salt thereof, cytidine 5′-monophosphate or a salt thereof, alkyl phosphate monoesters such as cytidine 5′-diphosphocholine sodium salt, methyl acid phosphate and butyl acid phosphate or salts thereof. The component B is preferably phenylphosphonic acid or a salt thereof from the viewpoint of improving the polishing rate and planarity.

The content of the component B in the polishing liquid composition of the present disclosure is preferably 0.001% by mass or more, more preferably 0.005% by mass or more, and further preferably 0.0075% by mass or more from the viewpoint of improving the polishing rate and planarity. From the same viewpoint, the content of the component B in the polishing liquid composition of the present disclosure is preferably 0.01 mM or more, more preferably 0.05 mM or more, and further preferably 0.1 mM or more, and preferably 5 mM or less, more preferably 3 mM or less, and further preferably 2 mM or less. More specifically, the content of the component B in the polishing liquid composition of the present disclosure is preferably 0.01 mM or more and 5 mM or less, more preferably 0.05 mM or more and 3 mM or less, and further preferably 0.1 mM or more and 2 mM or less. When the component Bis a combination of two or more kinds, the content of the component B refers to the total content of the two or more kinds.

[Nitrogen-Containing Heteroaromatic Compound (Component C)]

The polishing liquid composition of the present disclosure contains a nitrogen-containing heteroaromatic compound in which at least one hydrogen atom is substituted with a hydroxyl group (hereinafter, also referred to as a “component C” simply). The component C preferably contains at least one compound selected from an N-oxide compound containing a nitrogen-containing heteroaromatic ring skeleton in which at least one hydrogen atom is substituted with a hydroxyl group, and a salt of the N-oxide compound, from the viewpoint of improving the polishing rate and planarity. Examples of the salt include alkali metal salts, alkaline earth metal salts, organic amine salts, and ammonium salts. The component C may be used individually or in combination of two or more kinds.

In one or more embodiments of the present disclosure, the N-oxide compound may be a compound having an N-oxide group (N→O group). The N-oxide compound may have one or more than one N→O group, and preferably one N→O group in terms of availability.

In the present disclosure, at least one nitrogen atom in the nitrogen-containing heteroaromatic ring skeleton forms an N-oxide. In one or more embodiments, the nitrogen-containing heteroaromatic ring of the component C may be, e.g., a monocyclic or bicyclic condensed ring. In one or more embodiments, the number of nitrogen atoms in the nitrogen-containing heteroaromatic ring of the component C may be 1 to 3. The number of nitrogen atoms is preferably 1 or 2, and more preferably 1 from the viewpoint of improving the polishing rate and planarity. In one or more embodiments, the nitrogen-containing heteroaromatic ring skeleton of the component C may be at least one selected from a pyridine N-oxide skeleton, a quinoline N-oxide skeleton, or the like. In the present disclosure, the pyridine N-oxide skeleton indicates a configuration in which the nitrogen atom in the pyridine ring forms an N-oxide. The quinoline N-oxide skeleton indicates a configuration in which the nitrogen atom in the quinoline ring forms an N-oxide.

In one or more embodiments, the component C is at least one selected from an N-oxide compound having a pyridine ring in which at least one hydrogen atom is substituted with a hydroxy group, an N-oxide compound having a quinoline ring in which at least one hydrogen atom is substituted with a hydroxy group, and salts of these N-oxide compounds. Among them, the component B is preferably an N-oxide compound having a pyridine ring in which at least one hydrogen atom is substituted with a hydroxy group or a salt of the N-oxide compound, from the viewpoint of improving the polishing rate and planarity.

Examples of the component C include 2-hydroxypyridine N-oxide, 3-hydroxypyridine N-oxide, and 8-hydroxyquinoline N-oxide.

The content of the component C in the polishing liquid composition of the present disclosure is preferably 0.01 mM or more, more preferably 0.05 mM or more, and further preferably 0.1 mM or more from the viewpoint of improving the polishing rate and planarity. The component C is known to adsorb also on a silicon oxide film (object to be polished). It is considered that an excessively high content of the component C hinders the progress of polishing of the silicon oxide film at raised areas (wiring part) having a wide line width where a polishing load is less likely to be applied relatively, deteriorating the line width dependence. Therefore, the content of the component C in the polishing liquid composition of the present disclosure is preferably 5 mM or less, more preferably 3 mM or less, further preferably 0.8 mM or less, and still further preferably 2 mM or less from the viewpoint of reducing the line width dependence. More specifically, the content of the component C in the polishing liquid composition of the present disclosure is preferably 0.01 mM or more and 5 mM or less, more preferably 0.05 mM or more and 3 mM or less, and further preferably 0.1 mM or more and 2 mM or less. When the component C is a combination of two or more kinds, the content of the component C refers to the total content of the two or more kinds.

A molar ratio C/B of the content of the component C to the content of the component B in the polishing liquid composition of the present disclosure is preferably 0.01 or more, more preferably 0.05 or more, further preferably 0.1 or more, and still further preferably 0.5 or more, and preferably 100 or less, more preferably 20 or less, further preferably 10 or less, still further preferably 5 or less, and even further preferably 4 or less from the viewpoint of improving the polishing rate and planarity. The molar ratio C/B in the polishing liquid composition of the present disclosure is preferably 0.01 or more and 100 or less, more preferably 0.05 or more and 20 or less, further preferably 0.1 or more and 20 or less, still further preferably 0.5 or more and 20 or less, yet further preferably 0.5 or more and 5 or less, and even further preferably 0.5 or more and 4 or less.

[Aqueous Medium]

Examples of the aqueous medium contained in the polishing liquid composition of the present disclosure include water such as distilled water, ion-exchanged water, pure water and ultrapure water, and a mixed solvent of water and a solvent. The solvent may be any solvent that can be mixed with water (e.g., alcohol such as ethanol). When the aqueous medium is a mixed solvent of water and a solvent, the ratio of water to the total mixed medium may be any value that does not impair the effects of the present disclosure. For example, in terms of economy, the ratio is preferably 95% by mass or more, more preferably 98% by mass or more, and preferably less than 100% by mass. The aqueous medium is preferably water, more preferably ion exchanged water or ultrapure water, and further preferably ultrapure water in terms of the surface cleanliness of a substrate to be polished.

The content of the aqueous medium in the polishing liquid composition of the present disclosure may be a remainder after subtracting the component A, the component B, the component C, and optional components described below that are blended as needed, from the total amount of the polishing liquid composition.

[Optional Components]

The polishing liquid composition of the present disclosure may further contain optional components such as a pH adjustor, a surfactant, a thickener, a dispersant, a rust preventive, an antiseptic, a basic substance, a polishing rate improver, a silicon nitride film polishing inhibitor, and a polysilicon film polishing inhibitor. When the polishing liquid composition of the present disclosure further contains optional components, the content of the optional components in the polishing liquid composition of the present disclosure is preferably 0.001% by mass or more, more preferably 0.0025% by mass or more, and further preferably 0.01% by mass or more, and preferably 1% by mass or less, more preferably 0.5% by mass or less, and further preferably 0.1% by mass or less, from the viewpoint of improving the polishing rate and planarity. More specifically, the content of the optional components in the polishing liquid composition of the present disclosure is preferably 0.001% by mass or more and 1% by mass or less, more preferably 0.0025% by mass or more and 0.5% by mass or less, and further preferably 0.01% by mass or more and 0.1% by mass or less.

In one or more embodiments, the polishing liquid composition of the present disclosure may be free of metallic cations.

[Polishing Liquid Composition]

The polishing liquid composition of the present disclosure may be produced by a production method that includes a process of blending the component A, the component B, the component C, the aqueous medium, and the optional components as needed, by a known method. For example, the polishing liquid composition of the present disclosure may be produced by blending a dispersion (slurry) that contains the component A and the aqueous medium, a solution that contains the component B, the component C and the aqueous medium, and the optional components as needed. In the present disclosure, “blending” includes mixing the component A, the component B, the component C, the aqueous medium, and the optional components as needed simultaneously or in sequence. They can be mixed in any order. The blending can be performed, e.g., with a mixer such as a homomixer, a homogenizer, an ultrasonic disperser, or a wet ball mill. The blending amount (addition amount) of each component in the production method of the polishing liquid composition of the present disclosure may be the same as the content of each component in the polishing liquid composition of the present disclosure, as described above.

An embodiment of the polishing liquid composition of the present disclosure may be either a so-called one-part or two-part polishing liquid composition. The one-part polishing liquid composition is supplied to the market with all the components being mixed together. On the other hand, the components of the two-part polishing liquid composition are mixed at the time of use.

The pH of the polishing liquid composition of the present disclosure is preferably 4 or more, more preferably 4.5 or more, and preferably 8 or less, more preferably 7 or less, and further preferably 6.5 or less, from the viewpoint of improving the polishing rate and planarity. More specifically, the pH of the polishing liquid composition of the present disclosure is preferably 4 or more and 8 or less, and more preferably 4 or more and 6.5 or less from the same viewpoint. In the present disclosure, the pH of the polishing liquid composition is a value measured with a pH meter at 25° C. Specifically, the pH of the polishing liquid composition of the present disclosure can be measured by a method described in Examples.

The “content of each component in the polishing liquid composition” in the present disclosure refers to the content of each component at the time the polishing liquid composition starts to be used for polishing.

In one or more embodiments, the content of each component in the polishing liquid composition of the present disclosure may be the blending amount (addition amount) of each component in the polishing liquid composition of the present disclosure.

The polishing liquid composition of the present disclosure may be concentrated so as not to impair the stability, and stored and supplied in the concentrated state. This can reduce the production and transportation costs. If necessary, the concentrated solution may be appropriately diluted with the above-described aqueous medium for use in the polishing process. The dilution ratio is preferably 5 to 100 times.

[Film to be Polished]

The film to be polished with use of the polishing liquid composition of the present disclosure may be, e.g., a silicon oxide film that is formed in a production process of a semiconductor substrate. Therefore, the polishing liquid composition of the present disclosure can be used in a process requiring polishing of a silicon oxide film. In one or more embodiments, the polishing liquid composition of the present disclosure can be suitably used for the following purposes: polishing of a silicon oxide film in the process of forming an element isolation structure of a semiconductor substrate; polishing of a silicon oxide film in the process of forming an interlayer insulation film; polishing of a silicon oxide film in the process of forming embedded metal wiring; or polishing of a silicon oxide film in the process of forming an embedded capacitor. In another one or more embodiments, the polishing liquid composition of the present disclosure can be suitably used for the production of a three-dimensional semiconductor device such as a three-dimensional NAND flash memory.

[Polishing Liquid Kit]

One aspect of the present disclosure is directed to a kit for preparing the polishing liquid composition of the present disclosure (hereinafter, also referred to as a “polishing liquid kit of the present disclosure”).

The polishing liquid kit of the present disclosure may be, e.g., a polishing liquid kit (two-part polishing liquid composition), including an abrasive grain dispersion (first solution) that contains the component A and the aqueous medium and an additive aqueous solution (second solution) that contains the component B and the component C in a state in which the first solution and the second solution are not mixed together. They are mixed at the time of use and may be diluted as appropriate using the aqueous medium. The aqueous medium contained in the abrasive grain dispersion (first solution) may correspond to the whole or part of the amount of the aqueous medium used for the preparation of the polishing liquid composition. The additive aqueous solution (second solution) may contain a part of the aqueous medium used for the preparation of the polishing liquid composition. Each of the abrasive grain dispersion (first solution) and the additive aqueous solution (second solution) may contain the above-described optional components as needed. The abrasive grain dispersion (first solution) and the additive aqueous solution (second solution) may be mixed immediately before being supplied to the surface to be polished or may be separately supplied and mixed on the surface of a substrate to be polished. The polishing liquid kit of the present disclosure can provide a polishing liquid composition capable of improving the polishing rate for a silicon oxide film.

[Method for Producing Semiconductor Substrate]

One aspect of the present disclosure is directed to a method for producing a semiconductor substrate (hereinafter, also referred to as a “production method of a semiconductor substrate of the present disclosure”) that includes a process of polishing a film to be polished with use of the polishing liquid composition of the present disclosure (hereinafter, also referred to as a “polishing process with use of the polishing liquid composition of the present disclosure”). For example, the production method of a semiconductor substrate of the present disclosure relates to a method for producing a semiconductor device that includes a process of polishing the surface of a silicon oxide film that is opposite to the other surface in contact with a silicon nitride film, e.g., a step height of raised and trench areas of the silicon oxide film, with use of the polishing liquid composition of the present disclosure. The production method of a semiconductor device of the present disclosure enables high-speed polishing of a silicon oxide film, providing an effect of efficiently producing semiconductor devices.

The step height of raised and trench areas of the silicon oxide film may be spontaneously formed corresponding to a step height of the layer under the silicon oxide film when the silicon oxide film is formed by a chemical vapor deposition method or the like, or may be obtained by forming a step height of raised and trench areas using lithography or the like, for example.

The following describes an exemplary production method of a semiconductor substrate of the present disclosure. First, a silicon substrate is exposed to oxygen in an oxidation furnace so that a silicon dioxide layer is grown on the surface of the silicon substrate. Then, a polishing stopper film such as a silicon nitride (Si₃N₄) film or a polysilicon film is formed on the silicon dioxide layer by, e.g., a CVD (chemical vapor deposition) method. Next, a trench is formed by a photolithography technique in a substrate that includes the silicon substrate and the polishing stopper film provided on one of the main surfaces of the silicon substrate, e.g., in a substrate that includes the silicon substrate and the polishing stopper film provided on the silicon dioxide layer of the silicon substrate. Subsequently, a silicon oxide (SiO₂) film (i.e., a film to be polished) is formed to fill the trench by, e.g., a CVD method using a silane gas and an oxygen gas. Thus, a substrate to be polished in which the polishing stopper film is covered with the film to be polished (silicon oxide film) is obtained. Because of the formation of the silicon oxide film, the trench is filled with silicon oxide of the silicon oxide film, and the surface of the polishing stopper film that is opposite to the other surface facing the silicon substrate is covered with the silicon oxide film.

Consequently, the surface of the silicon oxide film that is opposite to the other surface facing the silicon substrate has a step height according to the raised and trench areas of the underlying layer. Then, the silicon oxide film is polished by a CMP method until at least the surface of the polishing stopper film that is opposite to the other surface facing the silicon substrate is exposed. More preferably, the silicon oxide film is polished until the surface of the silicon oxide film is flush with the surface of the polishing stopper film. The polishing liquid composition of the present disclosure can be used in this polishing process of the CMP method. The silicon oxide film has raised areas and trench areas according to the raised and trench areas of the underlying layer, and the width of the raised area may be, e.g., 0.5 μm or more and 5000 μm or less and the width of the trench area may be, e.g., 0.5 μm or more and 5000 μm or less.

In the polishing of the CMP method, the surface of the substrate to be polished is brought into contact with a polishing pad, and the substrate and the polishing pad are moved relative to each other while the polishing liquid composition of the present disclosure is being supplied to the contact area between them, so that the raised and trench areas of the surface of the substrate is planarized.

In the production method of a semiconductor substrate of the present disclosure, another insulation film may be formed between the silicon dioxide layer of the silicon substrate and the polishing stopper film. Alternatively, another insulation film may be formed between the film to be polished (e.g., the silicon oxide film) and the polishing stopper film (e.g., the silicon nitride film).

In the polishing process with use of the polishing liquid composition of the present disclosure, the rotation speed of the polishing pad may be, e.g., 30 to 200 rpm/min, the rotation speed of the substrate to be polished may be, e.g., 30 to 200 rpm/min, the polishing load set in the polishing device including the polishing pad may be, e.g., 20 to 500 g weight/cm², and the supply rate of the polishing liquid composition may be, e.g., 10 to 500 mL/min or less.

In the polishing process with use of the polishing liquid composition of the present disclosure, conventionally known materials and the like can be used as the materials and the like of the polishing pad. Examples of the materials of the polishing pad include organic macromolecular foams such as a hard polyurethane foam and non-foamed materials, and in particular, a hard polyurethane foam is preferable.

[Polishing Method]

One aspect of the present disclosure is directed to a polishing method that includes a process of polishing a film to be polished with use of the polishing liquid composition of the present disclosure, wherein the film to be polished is a silicon oxide film that is formed in a production process of a semiconductor substrate (hereinafter, also referred to as a “polishing method of the present disclosure”). The polishing method of the present disclosure can improve the polishing rate for the silicon oxide film, thus providing an effect of increasing the productivity of semiconductor substrates with improved quality. The specific polishing method and conditions may be the same as those of the production method of a semiconductor substrate of the present disclosure described above.

### EXAMPLES

Hereinafter, the present disclosure will be specifically described by way of examples. However, the following examples are not intended to limit the present disclosure.

1. Preparation of Polishing Liquid Composition

[Preparation of Polishing Liquid Compositions of Examples 1 to 14 and Comparative Examples 1 to 8]

The polishing liquid compositions of Examples 1 to 14 and Comparative Examples 1 to 8 were each prepared by mixing cerium oxide particles (component A) shown in Table 2, a compound (component B or non-component B) shown in Table 1 or 2, a nitrogen-containing heteroaromatic compound (component C) shown in Table 2, and water. Table 2 shows the addition amount (content) (% by mass or mM, active part) of each component in the polishing liquid compositions. The content of water was a remainder after subtracting the component A, the component B or non-component B, and the component C from the total amount of the polishing liquid composition. The pH was adjusted using ammonia or nitric acid.

The following material was used as cerium oxide particles (component A), as shown in Table 2.

Positively charged ceria (calcined crushed ceria, average primary particle diameter: 29 nm, BET specific surface area: 29 m²/g, surface potential 100 mV)

The following materials were used as compounds (component B or non-component B), as shown in Tables 1 to 2.

(Component B)
B1: Phenylphosphonic Acid [manufactured by TOKYO CHEMICAL INDUSTRY CO., LTD.]
B2: Creatinol Phosphate [manufactured by TOKYO CHEMICAL INDUSTRY CO., LTD.]
B3: Phosphocholine Chloride Sodium Salt Hydrate [manufactured by TOKYO CHEMICAL INDUSTRY CO., LTD.]
B4: Butylphosphonic Acid [manufactured by TOKYO CHEMICAL INDUSTRY CO., LTD.]
B5: Cytidine 5′-Monophosphate [manufactured by TOKYO CHEMICAL INDUSTRY CO., LTD.]
B6: Cytidine 5′-Diphosphocholine Sodium Salt [manufactured by TOKYO CHEMICAL INDUSTRY CO., LTD.](Non-Component B)
B7: Creatine Hydrate [manufactured by TOKYO CHEMICAL INDUSTRY CO., LTD.]
B8: 2-(Methacryloyloxy)ethyl 2-(Trimethylammonio)ethyl Phosphate [manufactured by TOKYO CHEMICAL INDUSTRY CO., LTD.]
B9: Polyvinylpyrrolidone [Polyvinylpyrrolidone K 30, manufactured by TOKYO CHEMICAL INDUSTRY CO., LTD.]

The following material was used as a nitrogen-containing heteroaromatic compound (component C), as shown in Table 2.

2-Hydroxypyridine N-oxide [manufactured by TOKYO CHEMICAL INDUSTRY CO., LTD.]

TABLE 1

| | Compound name | Structure |
|---|---|---|
| B1 | Phenylphosphonic Acid | 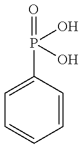 |
| B2 | Creatinol Phosphate | 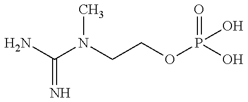 |
| B3 | Phosphocholine Chloride Sodium Salt Hydrate | 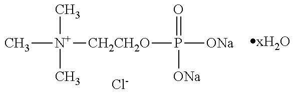 |
| B4 | Butylphosphonic Acid | 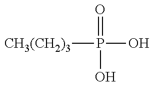 |
| B5 | Cytidine 5′-Monophosphate | 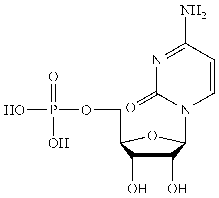 |
| B6 | Cytidine 5′- Diphosphocholine Sodium Salt | 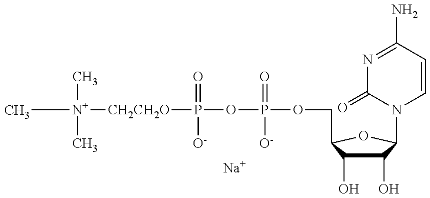 |
| B7 | Creatine Hydrate | 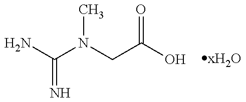 |
| B8 | 2-(Methacryloyloxy)ethyl 2- (Trimethylammonio)ethyl Phosphate | 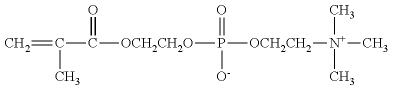 |
| B9 | Polyvinylpyrrolidone | 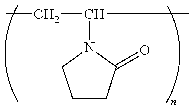 |

2. Measurement Method of Each Parameter

[pH of Polishing Liquid Composition]

The pH value at 25° C. of each of the polishing liquid compositions was measured with a pH meter (“HM-30G” manufactured by DKK-TOA CORPORATION).

Specifically, an electrode of the pH meter was immersed in the polishing liquid composition, and the pH value was obtained one minute after the immersion. Table 2 shows the results.

[Average Primary Particle Diameter of Cerium Oxide Particles]

The average primary particle diameter (nm) of the cerium oxide particles refers to a particle diameter (on a spherical shape basis) of the cerium oxide particles calculated according to the formula below using a specific surface area S (m²/g) that is determined by the BET (nitrogen adsorption) method.

The specific surface area S in the formula below was determined as follows. A slurry (10 g) of cerium oxide particles was dried under reduced pressure at 110° C. to remove moisture, followed by pulverization with an agate mortar. The specific surface area S of the resultant powder was measured with a fluid-type automatic specific surface area measurement apparatus FlowSorb 2300 (manufactured by Shimadzu Corporation).

Average primary particle diameter (nm)=820/S

[Surface Potential of Cerium Oxide]

The surface potential (mV) of the cerium oxide particles was measured with a surface potential measuring device (“ZetaProbe” manufactured by Kyowa Interface Science Co., Ltd.). The cerium oxide concentration was adjusted to 0.15% using ultrapure water. Then, the solution was introduced into the surface potential measuring device, and the surface potential was measured under the conditions that the particle density was 7.13 g/ml and the particle dielectric constant was 7. The measurement was carried out three times, and the average of the measured values was used as the measurement result.

3. Evaluation of Polishing Liquid Compositions (Examples 1 to 14 and Comparative Examples 1 to 8)

[Evaluation Sample]

Commercially available wafers for evaluating CMP characteristics (“P-TEOS CMP 464 PT wafer” manufactured by ADVANTEC, diameter: 200 mm) were cut to 40 mm×40 mm to prepare evaluation samples. The evaluation samples had a linear pattern of raised areas and trench areas formed by etching. Each raised area had a structure in which a 2000-nm-thick silicon oxide film was provided on a silicon substrate, and similarly the 2000-nm-thick silicon oxide film was provided in each trench area. A step height between the raised area and the trench area was 800 nm. The silicon oxide film was composed of P-TEOS. The silicon oxide film having a line width of the raised area and the trench area of 50 m, that having a line width of the raised area and the trench area of 500 μm, and that having a line width of the raised area and the trench area of 4 mm were used as measuring objects.

[Polishing Conditions]
Polishing device: TriboLab CMP (manufactured by Bruker)
Surface plate rotation speed: 100 rpm
Head rotation speed: 107 rpm
Polishing load: 99.3 N
Supply of polishing liquid: 50 mL/min
Polishing time: ⅓ minutes

[Polishing Rate]

The evaluation samples were polished with use of the polishing liquid compositions of Examples 1 to 14 and Comparative Examples 1 to 8 under the polishing conditions described above. The polished evaluation samples were cleaned with ultrapure water and dried to be measured with an optical interference type film thickness measuring device below.

The thicknesses of the silicon oxide film at raised areas before and after polishing were measured with an optical interference type film thickness measuring device (“VM-1230” manufactured by SCREEN Semiconductor Solutions Co., Ltd.). The polishing rate at raised areas of the silicon oxide film was calculated by the formula below. Table 2 shows the calculation results.

Polishing rate at raised areas (nm/min) [Thickness of silicon oxide film at raised areas before polishing (nm)−Thickness of silicon oxide film at raised areas after polishing (nm)]/Polishing time (min)

[Line Width Dependence]

The line width dependence was evaluated by calculating a difference between a polishing rate at raised areas having a line width of 4 mm and a polishing rate at the raised areas having a line width of 50 μm or 500 μm (polishing rate difference a, b). The polishing liquid composition with a smaller polishing rate difference was judged as having lower line width dependence. Table 2 shows the results.

In Table 2, the polishing rate difference a (nm/minute) is an absolute value of the difference between the polishing rate at raised areas having a line width of 4 mm and the polishing rate at raised areas having a line width of 50 μm. The polishing rate difference b (nm/minute) is an absolute value of the difference between the polishing rate at raised areas having a line width of 4 mm and the polishing rate at raised areas having a line width of 500 μm.

[Stability Over Time]

A crushed ceria slurry was prepared in the above-described manner, and the zeta potential of the slurry was measured with an electroacoustic high-concentration zeta potential analyzer (manufactured by Agilent Technologies, Inc.). The slurry was then left to stand in a 100 mL container at room temperature. After a lapse of one week, the zeta potential of the slurry was measured again to evaluate the stability over time in accordance with the following evaluation criteria. The slurry with a smaller variation in the value of zeta potential before and after storage was judged to be better in stability.

<Evaluation Criteria>
A: Variation in the value of zeta potential before and after storage was 30% or less.
B: Variation in the value of zeta potential before and after storage was more than 30% and 50% or less.
C: Variation in the value of zeta potential before and after storage was more than 50%.

TABLE 2

| | | | | | | | | | | | | Line width dependence | | |
|---|---|---|---|---|---|---|---|---|---|---|---|---|---|---|
| | Component | | | | | | | | | | | Polishing | Polishing | |
| | A | | | | | Component C | | | | | | rate | rate | |
| | Calcined | | | | | 2- | | | | | | difference a | difference b | |
| | crushed | Component B | | | | Hydroxypyridine | | | | | | Difference | Difference | |
| | ceria | Compound represented by Formula (I) or Formula (II) | | | | N-oxide | | | Polishing rate | | | between 4 | between 4 | |
| | Addition | | | | Addition | Addition | Molar | | 50 μm | 500 μm | 4 mm | mm [symbol] and | mm [symbol] and | Stability |
| | amount | | | | amount | amount | ratio | | [symbol] | [symbol] | [symbol] | 50 μm [symbol] | 500 μm [symbol] | over |
| | (mass %) | Kind | Compound name | Formula (I) or Formula (II) | (mM) | (mM) | C/B | pH | nm/min | nm/min | nm/min | nm/min | nm/min | time |
| Comp. | 0.15 | — | — | — | — | — | — | 5 | 192 | 222 | 186 | 6 | 36 | A |
| Ex. 1 | | | | | | | | | | | | | | |
| Comp. | 0.15 | — | — | — | — | 0.5 | — | 5 | 691 | 712 | 552 | 138 | 160 | A |
| Ex. 2 | | | | | | | | | | | | | | |
| Comp. | 0.15 | — | — | — | — | 3.0 | — | 5 | 751 | 430 | 101 | 650 | 329 | A |
| Ex. 3 | | | | | | | | | | | | | | |
| Comp. | 0.15 | B1 | Phenylphosphonic Acid | R1, R2 = OH, R3 = phenyl group, X1 = bond, n = 0 | 0.5 | — | — | 5 | 522 | 630 | 680 | 158 | 50 | C |
| Ex. 4 | | | | | | | | | | | | | | |
| Comp. | 0.15 | B1 | Phenylphosphonic Acid | R1, R2 = OH, R3 = phenyl group, X1 = bond, n = 0 | 3.0 | — | — | 5 | Untestable due to slurry sedimentation | | | | | — |
| Ex. 5 | | | | | | | | | | | | | | |
| Comp. | 0.15 | B7 | Creatine Hydrate (Non-Component B) | | 0.5 | 0.5 | 1.0 | 5 | 621 | 629 | 524 | 97 | 105 | A |
| Ex. 6 | | | | | | | | | | | | | | |
| Comp. | 0.15 | B8 | 2-(Methacryloyloxy)ethyl 2-(Trimethylammonio)ethyl Phosphate | | 0.5 | 0.5 | 1.0 | 5 | 691 | 727 | 577 | 114 | 150 | A |
| Ex. 7 | | | (Non-Component B) | | | | | | | | | | | |
| Comp. | 0.15 | B9 | Polyvinylpyrrolidone (Non-Component B) | | 0.5 | 0.5 | 1.0 | 5 | 684 | 695 | 560 | 124 | 135 | A |
| Ex. 8 | | | | | | | | | | | | | | |
| Ex. 1 | 0.15 | B1 | Phenylphosphonic Acid | R1, R2 = OH, R3 = phenyl group, X1 = bond, n = 0 | 0.5 | 0.25 | 0.5 | 5 | 857 | 812 | 860 | 3 | 48 | A |
| Ex. 2 | 0.15 | B1 | Phenylphosphonic Acid | R1, R2 = OH, R3 = phenyl group, X1 = bond, n = 0 | 0.5 | 0.5 | 1.0 | 5 | 862 | 846 | 870 | 8 | 24 | A |
| Ex. 3 | 0.15 | B1 | Phenylphosphonic Acid | R1, R2 = OH, R3 = phenyl group, X1 = bond, n = 0 | 0.125 | 0.5 | 4.0 | 5 | 830 | 810 | 825 | 5 | 15 | A |
| Ex. 4 | 0.15 | B1 | Phenylphosphonic Acid | R1, R2 = OH, R3 = phenyl group, X1 = bond, n = 0 | 0.5 | 2 | 4.0 | 5 | 810 | 790 | 798 | 12 | 8 | A |
| Ex. 5 | 0.15 | B1 | Phenylphosphonic Acid | R1, R2 = OH, R3 = phenyl group, X1 = bond, n = 0 | 2 | 2 | 1.0 | 5 | 821 | 811 | 830 | 9 | 19 | A |
| Ex. 6 | 0.15 | B1 | Phenylphosphonic Acid | R1, R2 = OH, R3 = phenyl group, X1 = bond, n = 0 | 0.25 | 0.5 | 2.0 | 5 | 841 | 821 | 831 | 10 | 10 | A |
| Ex. 7 | 0.15 | B1 | Phenylphosphonic Acid | R1, R2 = OH, R3 = phenyl group, X1 = bond, n = 0 | 0.05 | 0.5 | 10.0 | 5 | 795 | 760 | 770 | 25 | 10 | A |
| Ex. 8 | 0.15 | B1 | Phenylphosphonic Acid | R1, R2 = OH, R3 = phenyl group, X1 = bond, n = 0 | 0.025 | 0.5 | 20.0 | 5 | 691 | 712 | 730 | 39 | 18 | A |
| Ex. 9 | 0.15 | B1 | Phenylphosphonic Acid | R1, R2 = OH, R3 = phenyl group, X1 = bond, n = 0 | 0.5 | 0.1 | 0.2 | 5 | 600 | 660 | 698 | 98 | 38 | B |
| Ex. 10 | 0.15 | B2 | Creatinol Phosphate | R1, R2 = OH, R3 = 1-methylguanidino group, | 0.5 | 0.5 | 1.0 | 5 | 863 | 772 | 807 | 56 | 35 | A |
| | | | | X1 = ethylene group, n = 1 | | | | | | | | | | |
| Ex. 11 | 0.15 | B3 | Phosphocholine | R1, R2 = ONa, R3 = —N⁺ (CH3)3, | 0.5 | 0.5 | 1.0 | 5 | 858 | 730 | 796 | 62 | 66 | A |
| | | | Chloride Sodium Salt | X1 = ethylene group, n = 1 | | | | | | | | | | |
| | | | Hydrate | | | | | | | | | | | |
| Ex. 12 | 0.15 | B4 | Butylphosphonic Acid | R1, R2 = OH, R3 = butyl group, X1 = bond, n = 0 | 0.5 | 0.5 | 1.0 | 5 | 758 | 740 | 701 | 57 | 39 | A |
| Ex. 13 | 0.15 | B5 | Cytidine 5′- | R1, R2 = OH, R3 = cytidine group, X1 = bond, n = 1 | 0.5 | 0.5 | 1.0 | 5 | 726 | 636 | 692 | 34 | 56 | A |
| | | | Monophosphate | | | | | | | | | | | |
| Ex. 14 | 0.15 | B6 | Cytidine 5′- | R4, R5 = ONa, X2 = ethylene group , n1, n2 = 1, | 0.5 | 0.5 | 1.0 | 5 | 742 | 786 | 768 | 26 | 18 | A |
| | | | Diphosphocholine | Z1 = —N⁺(CH3)3, Z2 = cytidine group | | | | | | | | | | |
| | | | Sodium Salt | | | | | | | | | | | |

* Comparative Example: Comp. Ex., Example: Ex.

Table 2 shows that the polishing liquid compositions of Examples 1 to 14 achieved both of the improved polishing rate and the reduced line width dependence as compared with the polishing liquid compositions of Comparative Examples 1 to 4 and 6 to 8. Table 2 also shows that the polishing liquid compositions of Examples 1 to 14 were excellent in the stability over time.

The polishing liquid composition of Comparative Example 5 formed sediments and could not be evaluated.

### INDUSTRIAL APPLICABILITY

The polishing liquid composition according to the present disclosure is useful in a method for producing a high-density or high-integration semiconductor device.

1. A polishing liquid composition for a silicon oxide film, comprising:
cerium oxide particles (component A);
a compound represented by Formula (I) or Formula (II) below (component B);
a nitrogen-containing heteroaromatic compound in which at least one hydrogen atom is substituted with a hydroxyl group (component C); and
an aqueous medium, 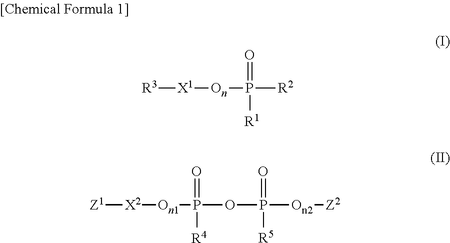
wherein in Formula (I), R¹ and R² are the same or different and represent a hydroxyl group or a salt thereof, R³ represents H, —NH₂, —NHCH₃, —N(CH₃)₂, —N⁺(CH₃)₃, an alkyl group, a phenyl group, a cytidine group, a guanidino group, or an alkylguanidino group, X¹ represents a bond or an alkylene group having 1 to 12 carbon atoms, and n represents 0 or 1, and
in Formula (II), R⁴ and R⁵ are the same or different and represent a hydroxyl group or a salt thereof, Z¹ represents H or —N⁺(CH₃)₃, Z² represents a cytidine group, X² represents a bond or an alkylene group having 1 to 12 carbon atoms, and n1 and n2 are the same or different and represent 0 or 1.

2. The polishing liquid composition according to claim 1, wherein in Formula (I), R¹ and R² are the same or different and represent a hydroxyl group or a salt thereof, R³ represents a phenyl group, a cytidine group, a guanidino group, or an alkylguanidino group, X¹ represents a bond or an alkylene group having 1 to 4 carbon atoms, and n represents 0 or 1.

3. The polishing liquid composition according to claim 1, wherein in Formula (I), R¹ and R² are the same or different and represent a hydroxyl group or a salt thereof, R³ represents a phenyl group, X¹ represents a bond, and n represents 0 or 1.

4. The polishing liquid composition according to claim 1, wherein the component C comprises at least one compound selected from the group consisting of an N-oxide compound containing a nitrogen-containing heteroaromatic ring skeleton in which at least one hydrogen atom is substituted with a hydroxyl group, and a salt of the N-oxide compound.

5. The polishing liquid composition according to claim 1, wherein the polishing liquid composition comprises the component B in an amount of 0.01 mM or more and 5 mM or less.

6. The polishing liquid composition according to claim 1, wherein the polishing liquid composition comprises the component C in an amount of 0.01 mM or more and 5 mM or less.

7. The polishing liquid composition according to claim 1, wherein a molar ratio C/B of the content of the component C to the content of the component B is 0.5 or more and 20 or less.

8. The polishing liquid composition according to claim 1, wherein the polishing liquid composition comprises the component A in an amount of 0.001% by mass or more and 6% by mass or less.

9. The polishing liquid composition according to claim 1, wherein the polishing liquid composition has a pH of 4 or more and 8 or less at 25° C.

10. The polishing liquid composition according to claim 1, wherein the polishing liquid composition has a pH of 4 or more and 6.5 or less at 25° C.

11. A method for producing a semiconductor substrate, comprising a process of polishing a film to be polished with use of the polishing liquid composition according to claim 1.

12. A polishing method, comprising a process of polishing a film to be polished with use of the polishing liquid composition according to claim 1,
wherein the film to be polished is a silicon oxide film that is formed in a production process of a semiconductor substrate.
